(19) United States
(12) Patent Application Publication
(10) Pub. No.: US 2015/0287891 A1
(43) Pub. Date: Oct. 8, 2015

(54) LED Packaging Structure Using Distant Fluorescent Powder Layer and Manufacturing Method Thereof

(71) Applicant: HKUST LED-FPD TECHNOLOGY R&D CENTER AT FOSHAN, Guangdong (CN)

(72) Inventors: Huihua Liu, Guangdong (CN); Chichuen Lo, Guangdong (CN); Rong Zhang, Guangdong (CN); Shiwei Lee, Guangdong (CN)

(73) Assignee: HKUST LED-FPD TECHNOLOGY R&D CENTER AT FOSHAN, Guangdong (CN)

(21) Appl. No.: 14/428,775

(22) PCT Filed: Nov. 25, 2013
(86) PCT No.: PCT/CN2013/087761

§ 371 Date: Mar. 17, 2015

(30) Foreign Application Priority Data
Dec. 24, 2012 (CN) 201210568404.1

(51) Int. Cl. H01L 33/50; F21K 99/00

(52) U.S. Cl. CPC H01L 33/505; F21K 9/56; H01L 2933/0041; F21Y 2101/02

(57) ABSTRACT

Disclosed is an LED packaging structure using a distant fluorescent powder layer and a manufacturing method thereof. A fluorescent powder layer (10) with a recessed cavity cover structure is used in the packaging structure. A group of dies for manufacturing the fluorescent powder layer are specifically designed in the present invention. The fluorescent powder layer manufactured by using the dies has a regular structure and an even thickness. The fluorescent powder layer and a substrate (30) form a closed cavity for accommodating a chip (20) on the substrate, the cavity is vacuum, and the effect of distant fluorescent powder coating can be achieved. The manufacturing method can be also used for batch manufacturing of the fluorescent powder layers, and repeated adhesive dispensing for each chip in the traditional batch packaging process of the fluorescent powder layers is avoided, thereby improving the LED packaging efficiency.

### RELATED APPLICATIONS

The present application is a national stage of, and claims priority to, PCT/CN2013/087761, filed Nov. 25, 2013, which claims priority to Chinese patent application CN201210568404.1, filed Dec. 24, 2012, the entireties of which are incorporated herein.

### FIELD

The present disclosure generally relates to the field of LED packaging technology, particularly, to preparation of a phosphor structure with uniform thickness and more particularly to a LED packaging structure with remote phosphor layer and preparation method thereof.

### BACKGROUND

Light emitting diode (LED) is a solid-state semiconductor device, which converts electrical energy directly into optical energy. The working principle of LED is different from the incandescent lamps and fluorescent light. The LED has the advantages of long life, high efficiency, low radiation and low power consumption. Usually, the irradiation spectrum of LED is almost within visible range. Accordingly, the light efficiency can exceed 1501 m/W (in the year 2010).

LED packaging is the packaging of luminous chip, which is significant different from conventional integrated circuit packaging. Encapsulant material not only protects the chip and the interconnects, but also is the light emission path. As a result, there are specific requirements to the packaging materials. LED chip is usually encapsulated by transparent silicone mixed with phosphor particles. Silicone is mainly used to protect the LED chip and relevant electronic components, and the phosphor is mainly used to produce white light (for example, yellow phosphor can convert light emitted from a blue LED chip into white light). There are various packaging structures depending on the requirements of thermal design, luminous efficiency, color index and reliability.

In a typical white LED package, a LED chip is mounted in a leadframe within a reflective cup. The reflective cup is filled with phosphor and silicone. The chip is covered by phosphor particles. The periphery of the phosphor is filled with silicone. Blue light emitted from the chip is converted by the phosphor into yellow light. White light is finally emitted from the package after the blue light is mixed with the yellow light. Light is scattered in all directions when it hits the phosphor particles, or reflected by the reflective cup.

In a traditional packaging structure, the phosphor is applied directly on the periphery of the chip. This means light emitted from the chip reaches the phosphor immediately. This has two disadvantages. First, part of the light is back scattered to the chip and interferes with the light emitted from the chip. Second, the heat generated by the chip is directly transferred to the phosphor, which increases the phosphor temperature, thus reduces the life of the phosphor and the reliability of the LED lamp.

To address the above two problems, the latest technology of remote phosphor coating improves the packaging design of the chip and the phosphor. A phosphor layer is placed apart from the chip, and the gap in-between the phosphor layer and the chip is either vacuum or filled with transparent materials. The remote phosphor coating is widely adopted, and there are many patent applications related to the technology in various countries. There is no standard for remote phosphor coating technology. Generally, remote phosphor means placing phosphor materials apart from the chip.

There are some drawbacks in the existing phosphor dispensing method. In a common a LED chip package, a lot of phosphor gel is filled and sealed into the reflection cup to achieve the effect of emitting white light. It consumes a lot of phosphor materials and hence increases the overall cost. Uneven distribution of phosphor particles is another disadvantage of dispersed phosphor dispensing method. This leads to poor angular color temperature and intensity uniformity. Conformal coating is another phosphor deposition method. Phosphor is coated on the surface of the chip by spraying, photolithography and thin film technologies. This shape-preserving coating technology has low throughput. Also, there is another technology that slightly controls the geometry of the phosphor by coating phosphor only around the chip. But this often produces a phosphor layer with non-uniform thickness and irregular shape due to poor process control.

### SUMMARY OF THE INVENTION

An embodiment of the present invention comprises LED packaging structure includes a substrate, a LED chip and a phosphor layer, wherein the LED chip is fixed on the substrate, the phosphor layer is cap-like and has a cavity; the phosphor layer is bonded on the substrate, and forming a closed cavity with the substrate, with the LED chip located inside the cavity; the volume of the cavity is larger than the volume of the LED chip, and the gap between the chip and the phosphor layer is vacuum.

In one embodiment, the cavity may be cylindrical, hemispherical or polygonal in shape.

The present disclosure also provides a phosphor layer for the above LED packaging structure.

A phosphor layer for the above LED packaging structure is cap-like and has a cavity, and has a uniform thickness.

In one embodiment, the cavity may be cylindrical, hemispherical or polygonal in shape.

The present disclosure also provides a preparation method for the above phosphor layer.

A method of preparing the phosphor layer for LED packaging includes the following steps: providing a male mold and a female mold that match with each other, wherein the female mold has at least one cavity, and the male mold has the extruding feature that matches with the cavity; dispense phosphor slurry into the cavity of the female mold; close the female mold with the male mold on the female mold, wherein a distance between walls of the convex portion of the male mold and the concave cavity of the female mold is greater than zero when the male mold is fitted on the female mold; and obtaining a cap-like phosphor layer with a cavity after curing and demolding.

The present disclosure also provides a mold for preparing the above phosphor layer. A mold for preparing the above phosphor layer comprises of a male mold and a female mold that match each other; the male mold has at least one extruding feature, and the female mold has at least one cavity, The extruding feature of the male mold matches with the cavity of the female mold; a distance between inner walls of the convex portion of the male mold and the concave cavity of the female mold is greater than zero.

The present disclosure also provides a method of preparing the above LED packaging structure.

A method of preparing the above LED packaging structure includes the steps of:

a. Die bonding: fixing a LED chip onto a substrate by die attach adhesive by a die bonder;

b. Wire bonding: the electrical interconnects between the chip and the substrate are by gold wire bonds;

c. Preparing phosphor layer: preparing a phosphor layer by the method of preparing the phosphor layer of claim 5;

d. Phosphor layer bonding: bonding the phosphor layer on the substrate by silicone, with the LED chip covered within a cavity of the phosphor layer, the LED packaging structure is obtained after curing.

The design principles of the present disclosure are listed as follows.

Disadvantages of the prior art to be overcome:

a. Conformal phosphor coating has poor light extraction efficiency due to the back scattering of the light; phosphor is directly heated by the chip, which may cause reliability problems.

b. Irregular structure and a non-uniform thickness of the phosphor layer due to poor process control.

c. Conformal coating technology which can obtain a regular structure, a uniform thickness and a controllable precision is expensive

d. Dispersed dispensing method is slow. Phosphor slurry is dispensed into one reflective cup each time only.

Phosphor layer design: in order to realize remote excitation and obtain a phosphor layer with a regular structure and a uniform thickness, the diameter and height of a phosphor layer cover is determined according to the dimension of the chip; the phosphor layer is cap-like and has a cavity, each cavity accommodates one LED chip. Such structure can separate the chip and the phosphor layer so as to realize remote excitation of the phosphor particles. The distance between the chip and the phosphor layer can be adjusted by proper mold design. (for example, hundreds of microns).

Mold design and preparing of the phosphor layer: in order to easily obtain the above phosphor layer, a male mold and a female mold that match each other are used. A number of cavities are arranged in the female mold, while corresponding extruding features are arranged on the male mold. The shape of the phosphor layer is determined by the male and female mold design. The shape and size of the concave cavity of the female mold are the same as that of the concave cavity of the phosphor layer to be prepared. Phosphor slurry is dispensed into the female mold. The female mold is closed by the male mold. The phosphor layer is obtained after curing and demolding.

The phosphor layer may be an array structure; the concave cavities in the array are separated from each other in the upper walls with only the bottoms connected to ensure the independence of each LED unit after singulation.

The phosphor layer itself plays a role in protecting the chip and wires, it is not necessary to fill the gap with encapsulation materials.

Technological processes: Performing LED batch die bonding and wire bonding, prepare phosphor layers using a set of molds which have already been designed according to the production scale, and implementing LED batch packaging in a simple way.

The process procedure are listed as follows: 1. Preparing silicon substrate; 2. Die bonding; 3. Wire bonding; 4. Preparing phosphor slurry; 5. Preparing phosphor layer by molding; 6. Curing; 7. Demolding; 8. Aligning the phosphor layer and chip; 9. Bonding; and 10. Wafer dicing.

Description: the design drawing which shows a 4*4 array (FIG. 4 or FIG. 5) is just a schematic diagram. There is no limitation in the size of the array. The actual number and size of arrays may depend on the dimension of the wafer-level silicon substrate and the distribution of the LED chip on the substrate.

The present disclosure has the following advantages.

In the LED packaging structure of the present disclosure, the phosphor layer is cap-like and has a cavity ,which a LED chip is located inside, with a gap between the phosphor layer and the LED chip. This realizes remote excitation of the phosphor and overcomes the problems in the prior art that conformal phosphor coating would result in a poor light extraction efficiency, and the reliability of the phosphor would be weakened due to the heat of phosphor.

For the preparation method for the phosphor layer, the present disclosure uses a pair of molds that match each other. The pair of molds includes a male mold and a female mold, wherein the female mold is has at least one cavity, and the male mold has at least one corresponding extruding feature. The phosphor layer prepared with these molds has a regular structure and a uniform thickness. The molds are also applicable to batch preparation of the phosphor layers. The present disclosure overcomes the disadvantage caused by a lot of repetitive operation that the chips should be coated by the phosphor one by one in the traditional batch dispensing process.

Compared with the existing technologies which have non-uniform coating thickness, the present disclosure is more applicable to mass production, and saves costs molding. Compared with the existing technologies of remote packaging of phosphor layer, the present disclosure can produce a new structure of phosphor layer which is more uniform with a higher precision and able to achieve excitation in all angles.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment.

FIG. 1 is a schematic diagram illustrating a phosphor layer according to Embodiment One of the present disclosure (batch production).

FIG. 2 is a schematic diagram illustrating an assembly of a phosphor layer and wafer-level LED substrate according to Embodiment One of the present disclosure.

FIG. 3 is a sectional diagram of the assembly in Embodiment One of the present disclosure.

FIG. 4 is a schematic diagram illustrating a structure of a female mold according to Embodiment One of the present disclosure.

FIG. 5 is a schematic diagram illustrating a structure of male mold according to Embodiment One of the present disclosure.

FIG. 6 is sectional diagram of an assembly of the molds in Embodiment One of the present disclosure.

FIG. 7 is a schematic diagram illustrating a phosphor layer according to Embodiment Two of the present disclosure (batch production).

FIG. 8 is a schematic diagram illustrating an assembly of a phosphor layer and wafer-level LED substrate according to Embodiment Two of the present disclosure.

FIG. 9 is a sectional diagram of the assembly in Embodiment Two of the present disclosure.

FIG. 10 is a schematic diagram illustrating a female mold according to Embodiment Two of the present disclosure.

FIG. 11 is a schematic diagram illustrating a male mold according to Embodiment Two of the present disclosure.

FIG. 12 is sectional diagram of an assembly of the molds in Embodiment Two of the present disclosure.

### DETAILED EMBODIMENTS

In the following description of embodiments, reference is made to the accompanying drawings which form a part hereof, and in which it is shown by way of illustration specific embodiments of the disclosure that can be practiced. It is to be understood that other embodiments can be used and structural changes can be made without departing from the scope of the disclosed embodiments.

The materials used in the embodiment are listed as follows.

Devices and materials: wafer-level silicon substrate, die attach adhesive, normal 1W LED chip (1 mm×1mm), gold wire, phosphor, DowCorning 6650 silicone, two pieces of aluminum master mould, die bonder, high temperature oven, moulding machine tool, moulding machine and dicing machine.

Embodiment One

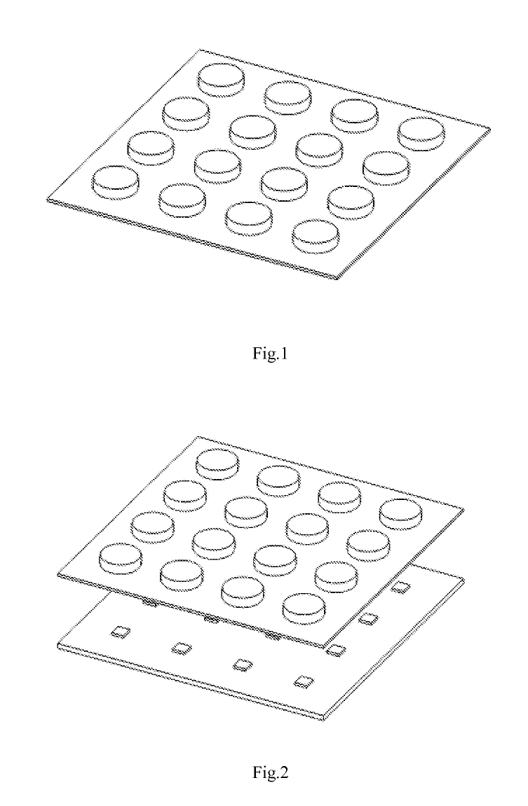

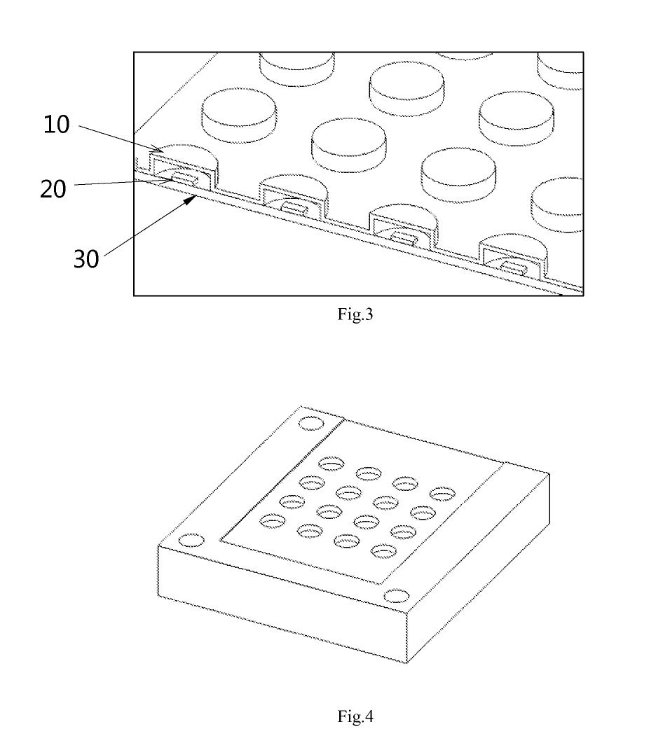

With reference to FIGS. 1-3, a LED packaging structure includes a substrate 30, a LED chip 20 and a phosphor layer 10. The LED chip 20 is fixed on the substrate 30. the phosphor layer 10 has a cavity, and the phosphor layer is bonded on the substrate. The phosphor layer and the substrate form a closed cavity, which accommodates a LED chip thereof. The volume of the concave cavity is larger than the volume of the LED chip, and there is a gap provided between the phosphor layer and the LED chip.

The cavity has a dome shape.

The preparation method for the above phosphor layer includes: providing a male mold and a female mold that match each other, wherein the female mold has at least one cavity, and the male mold has at least one extruding feature that matches with the cavity; a distance between walls of the extruding feature of the male mold and the cavity of the female mold is greater than zero when the male mold is fitted on the female mold; dispense phosphor gel into the concave cavity of the female mold; cover the male mold on the female mold, wherein; and obtaining a cap-like phosphor layer after curing and demolding.

A male mold (see FIG. 4) and a female mold (see FIG. 5) that matches with the male mold in shape are fabricated by machining The size of the male mold is 37 mm long and 34 mm wide, and has 16 cylindrical extruding features. The size of the female mold is 37 mm long and 34 mm wide, and has 16 cylindrical cavities. The extruding features in the male mold have a diameter of 2.6 mm and a height of 0.8 mm, and the pitch is 5.06 mm. The cavities in the female mold have a diameter of 3 mm and a depth of 0.8 mm, and the pitch is 5.06 mm.

The height of the extruding feature in the male mold is 0.8 mm.

The thickness of the phosphor layer is 0.2 mm.

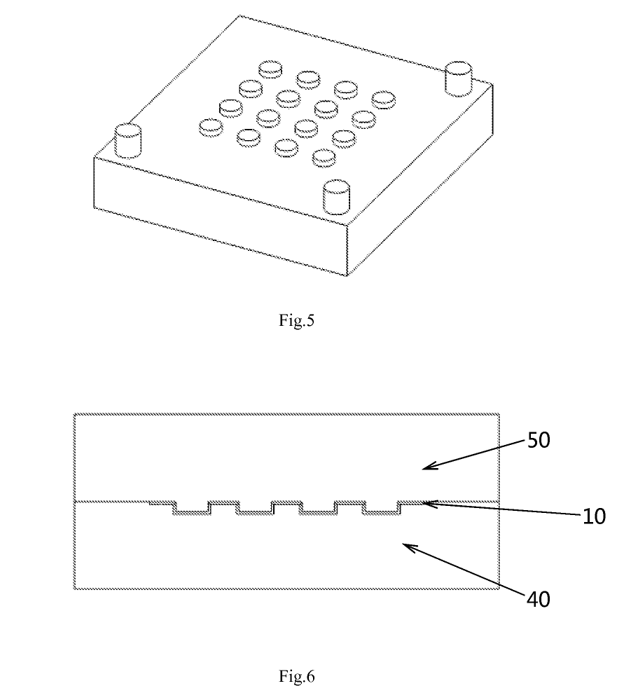

Alignment hole: three corners of the square base of the female mold are provided with three alignment holes, and three corners of the square base of the male mold are provided with three alignment pins corresponding to the alignment holes. When the male mold and the female mold are engaged for molding (see FIG. 6), the gap between the cavity in the female mold and the extruding feature in the male mold(i.e., the thickness of the phosphor layer) is 0.2 mm.

The phosphor layer prepared by the method has a regular structure and uniform thickness.

The preparation method for the above LED packaging structure includes:

a. Die bonding: fixing a LED chip onto a substrate by a die attach adhesive in a die bonder.

16 LED chips are bonding on the wafer-level silicon substrate by the die attach adhesive in the die bonder, and the pitch is 5.06 mm.

b. Wire bonding: the electrical interconnects between the chip and the substrate are made by gold wire bonding.

The gold wire is used to form wire bonding between electrodes of the chip and outer bonding area by pressure bonding, hot bonding or ultrasonic bonding.

c. Phosphor layer preparing: preparing a phosphor layer by the above preparation method for the phosphor layer.

The phosphor is mixed with the silicone and dispensed into each of the cylindrical cavity of the female mold. It is then placed in a vacuum environment for degassing. The male mold and the female mold are coupled in the molding machine to form a phosphor layer.

Phosphor layer curing: the curing profile of silicone material is used (the curing time of the DowCorning 6650 silicone is one hour at 150 degree centigrade).

d. Phosphor layer bonding: bonding the phosphor layer to the substrate by silicone, with the LED chip covered within a cavity of the phosphor layer, and performing curing to obtain the LED packaging structure.

The phosphor layer array is aligned to the chips on the wafer-level silicon substrate; the phosphor layer is bonded to the chip by the silicone, and a closed gap is formed within each of the phosphor cover which surrounds the chip. Curing is performed again.

The wafer-level silicon substrate with phosphor layer is placed on a working platform of a dicing machine for wafer dicing to obtain a plurality of single packaged LED units.

Embodiment Two

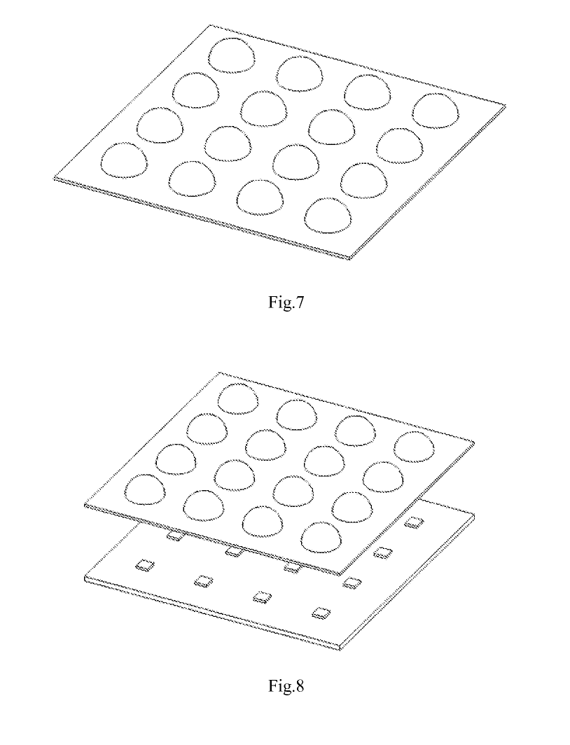

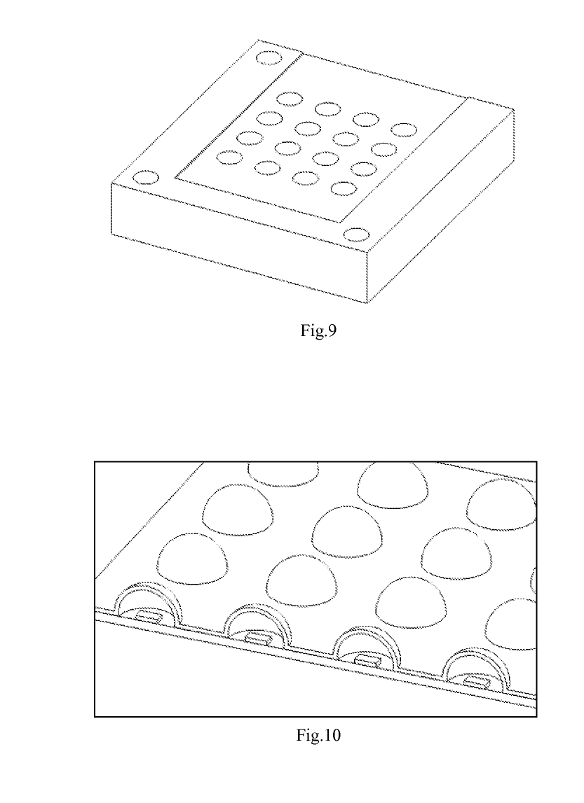

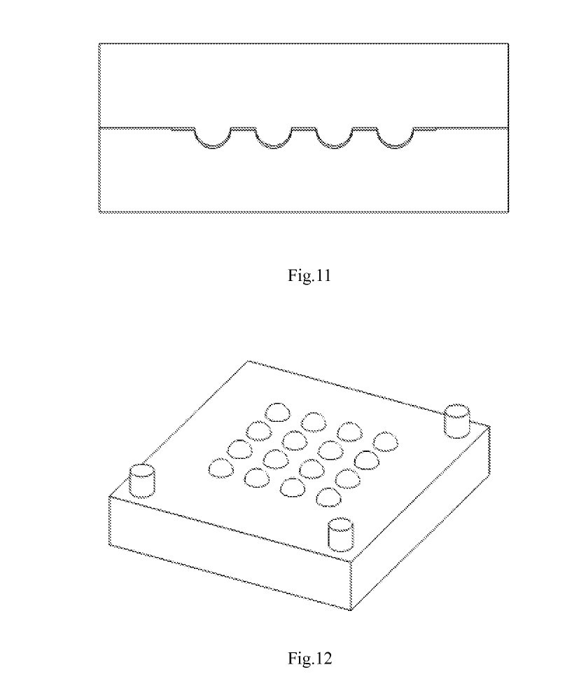

With reference to FIGS. 7-9, a LED packaging structure includes a substrate, a LED chip and a phosphor layer, wherein the LED chip is fixed on the substrate, the phosphor layer has a cavity, the phosphor layer is bonded on the substrate, the phosphor layer and the substrate form a closed cavity, the LED chip is located in the cavity, the volume of the concave cavity is larger than the volume of the LED chip, there is a vacuum gap provided between the phosphor layer and the LED chip.

The cavity is hemispherical in shape.

The preparation method for the above phosphor layer includes: providing a male mold and a female mold that match each other, wherein the female has at least one cavity, and the male mold has at least one extruding feature that matches with the cavity; a distance between walls of the extruding feature of the male mold and the cavity of the female mold is greater than zero when the male mold is fitted on the female mold; dispense phosphor slurry into the concave cavity of the female mold; covering the male mold on the female mold, wherein; and obtaining a cap-like phosphor after curing and demolding.

A male mold (see FIG. 10) and a female mold (see FIG. 11) that matches with the male mold in shape are fabricated by machining The size of the male mold is 37 mm long and 34 mm wide, and has 16 hemispherical extruding features. The size of the female mold is 37 mm long and 34 mm wide, and has 16 hemispherical cavities. The extruding features in the male mold have a diameter of 2.6 mm and a height of 0.8 mm, and the pitch is 5.06 mm. The concave cavities in the female mold have a diameter of 3 mm and a depth of 0.8 mm, and the pitch is 5.06 mm.

The height of the extruding feature in the male mold is 0.8 mm.

The thickness of the phosphor layer is 0.2 mm.

Alignment hole: three corners of the square base of the female mold are provided with three alignment holes, and three corners of the square base of the male mold are provided with three alignment pins corresponding to the alignment holes. When the male mold and the female mold are engaged for molding (see FIG. 6), the gap between the cavity of the female mold and the extruding feature of the male mold (i.e., the thickness of the phosphor layer) is 0.2 mm.

The phosphor layer prepared by the method has a regular structure and uniform thickness.

The preparation method for the above LED packaging structure includes:

a. Die bonding: fixing a LED chip onto a substrate by a die attach adhesive in a die bonder.

16 LED chips are bonded on the wafer-level silicon substrate by the die attach adhesive in the die bonder, and the pitch is 5.06 mm.

b. Wire bonding: the electrical interconnects between the chip and the substrate are made by gold wire bonding.

The gold wire is used to wire bonding between electrodes of the chip and outer bonding area by pressure bonding, hot bonding or ultrasonic bonding.

c. Phosphor layer preparing: preparing a phosphor layer by the above preparation method for the phosphor layer.

The phosphor is mixed with the silicone and dispensed into each of the cavity of the female mold for vacuum. It is then placed in a vacuum environment for degassing. The male mold and the female mold are coupled in the molding machine to form a phosphor gel.

Phosphor layer curing: the curing profile of silicone material is used (the curing time of the DowCorning 6650 silicone is one hour at 150 degree centigrade).

d. Phosphor layer bonding: bonding the phosphor layer to the substrate by silicone, with the LED chip covered within a cavity of the phosphor layer, and performing curing to obtain the LED packaging structure.

The phosphor layer array is aligned to the chips on the wafer-level silicon substrate, the phosphor layer is bonded to the chip by the silicone, and a closed gap is formed within each of the phosphor cover which surrounds the chip. Curing is performed again.

The wafer-level silicon substrate with phosphor layer is placed on a working platform of a dicing machine for wafer dicing to obtain a plurality of single packaged LED units.

The embodiments are chosen and described to explain the principles of the disclosure and their practical application so as to activate others skilled in the art to utilize the disclosure, and various embodiments and with various modifications as are suited to the particular use contemplated. Alternative embodiments will become apparent to those skilled in the art to which the present disclosure pertains without departing from its spirit and scope. For example, the LED substrate can be changed to another type of substrate, the batch packaging can be applied to single LED packaging, and the phosphor layer structure can be prepared by other molding process. Accordingly, the scope of the present disclosure is defined by the appended claims rather than the foregoing description and the exemplary embodiments described therein.

What is claimed is:

1. A LED packaging structure, comprising: a substrate, a LED chip and a phosphor layer, wherein the LED chip is fixed on the substrate, the phosphor layer is cap-like and has a cavity; the phosphor layer is bonded on the substrate, and forming a closed cavity with the substrate, with the LED chip covered within the cavity; the volume of the concave cavity is larger than the volume of the LED chip, and a vacuum gap is provided between the phosphor layer and the LED chip.

2. The LED packaging structure of claim 1, wherein the cavity is cylindrical, hemispherical or polygonal in shape.

3. A phosphor layer for LED packaging, wherein the phosphor layer is cap-like and has a cavity, and has a uniform thickness.

4. The phosphor layer for LED packaging of claim 3, wherein the cavity is cylindrical, hemispherical or polygonal in shape.

5. A method of preparing the phosphor layer for LED packaging of claim 3, comprising the steps of:
providing a male mold and a female mold that match each other, wherein the female mold has at least one cavity, and the male mold has at least one extruding feature that matches with the cavity;
injecting phosphor slurry into the cavity of the female mold;
coupling the male mold on the female mold, wherein a distance between walls of the convex portion of the male mold and the concave cavity of the female mold is greater than zero when the male mold is fitted on the female mold; and
obtaining a phosphor layer of a cover structure with a cavity after curing and demoulding.

6. A Mold for preparing the phosphor layer of claim 3, wherein the mold comprises a male mold and a female mold that match each other; the male mold has at least one extruding feature, and the female mold has at least one cavity, with one-to-one correspondence between each extruding feature and each cavity; a distance between inner walls of the convex portion of the male mold and the concave cavity of the female mold is greater than zero.

7. A method of preparing the LED packaging structure of claim 1, comprising the steps of:
a. Die bonding: fixing a LED chip on a substrate by a die attach adhesive in a die bonder;
b. Wire bonding: using gold wire to form wire bonding between electrodes of the chip and outer lead bonding area;
c. Preparing phosphor layer: preparing a phosphor layer by the method of preparing the phosphor layer of claim 5;
d. Phosphor layer bonding: bonding the phosphor layer and the substrate by using silicone, with the LED chip covered within a cavity of the phosphor layer, and performing curing to obtain the LED packaging structure.
